(19) United States
(12) Patent Application Publication
(10) Pub. No.: US 2011/0073186 A1
(43) Pub. Date: Mar. 31, 2011

(54) TARGET FOR A SPUTTERING PROCESS FOR MAKING A COMPOUND FILM LAYER OF A THIN SOLAR CELL, METHOD OF MAKING THE THIN FILM SOLAR CELL, AND THIN FILM SOLAR CELL MADE THEREBY

(75) Inventors: Chih-Huang LAI, Hsinchu (TW); Chia-Hsiang CHEN, Beidou Township (TW); Yi-Chang CHEN, Zhonghe City (TW)

(73) Assignee: Chih-Huang LAI, Hsinchu (TW)

(21) Appl. No.: 12/880,481

(22) Filed: Sep. 13, 2010

(30) Foreign Application Priority Data
Sep. 25, 2009 (TW) 098132508

(51) Int. Cl. H01L 31/0272; H01B 1/02; C23C 14/14; C23C 14/34

(52) U.S. Cl. 136/262; 252/519.14; 204/298.13; 204/192.1; 136/264; 136/265

(57) ABSTRACT

A target adapted for a sputtering process for making a compound film layer of a thin film solar cell includes a composition having a formula of CuB₁₋ₓCₓSe_{y}S_{2-y}, wherein B and C are independently selected from Group IIIA elements; x ranges from 0 to 1; and y ranges from 0 to 2. A thin film solar cell made by sputtering using the target and a method of making the thin film solar cell are also disclosed. Specifically, the thin film solar cell includes a compound film formed with substantially columnar grains. The energy gap of the compound film layer may be varied using different work pressures during a sputtering process. At least one interlayer may be included in the compound film layer to control the size of columnar grains in the compound film layer.

### CROSS-REFERENCE TO RELATED APPLICATION

This application claims priority of Taiwanese Application No. 098132508, filed on Sep. 25, 2009. The contents of the preceding application are hereby incorporated in its entirety by reference into this application.

### BACKGROUND OF THE INVENTION

1. Field of the Invention

The invention relates to a target for a sputtering process, more particularly to a target for a sputtering process for making a compound film layer of a thin film solar cell. The invention also relates to a method of making the thin film solar cell and the thin film solar cell made by the method.

2. Description of the Related Art

Among various thin film solar cells, CIGS (copper indium gallium diselenide) thin film solar cell is most valuable because of its properties, such as high photoelectric efficiency, light absorption ranging from 1.02 eV to 1.68 eV, light absorption rate (α) of more than 10⁴-10⁵ cm⁻¹, a photoelectric material thickness that is less than 1 μm, an absorption of more than 99% of photons, etc.

Referring to FIG. 1, the CIGS thin film solar cell 100 includes a substrate 11, aback electrode 12 formed on the substrate 11, a compound film layer 13 formed on the back electrode 12, and a top electrode 14 formed on the compound film layer 13.

The substrate 11 is usually made of glass, a flexible foil of metal or alloy, or polymer. The back electrode 12 is a molybdenum layer that is 0.5-1.0 μm in thickness and that is formed using a molybdenum target. The compound film layer 13 is a copper indium gallium diselenide (CuIn₁₋ₓGaₓSe₂) layer that is 1.0-2.0 μm in thickness, and absorbs photons and produces photocurrent via a photovoltaic effect upon being irritated by light. The top electrode 14 is made of aluminum. The photocurrent can be conducted via the back electrode 12 or the top electrode 14.

The CIGS thin film solar cell 100 further includes, between the top electrode 14 and the compound film layer 13, a cadmium sulfide buffering layer for enhancing the effective conduction of electrons, a zinc oxide film layer for preventing the compound film layer 13 from shunting when producing the photocurrent, and a transparent window layer of aluminum zinc oxide. Since these layers are well known structures in the art, they are not described in detail herein.

In the thin film solar cell 100, carriers are directed along a direction substantially normal to the surface thereof. When the carriers are transmitted along the normal direction in the compound film layer 13, they are liable to be scattered and trapped due to the existence of the grain boundary, which results in electricity loss and reduces the efficiency of the solar cell.

Referring to FIG. 2, conventionally, the compound film layer 13 is formed by thermal evaporation and has a relatively large grain size. As shown in FIG. 2, the shape of the grains is irregular and the size distribution of the grains is not uniform. The problem of electricity loss due to the grain boundary still exists in the prior art.

U.S. Pat. No. 5,141,564 discloses a thin film heterojunction solar cell that includes a p-type layer comprising a mixed ternary I-III-VI₂ polycrystalline semiconductor material (CuIn₁₋ₓGa₂Se, x preferably ranging from 0.25 to 0.35) and having a composition gradient in the direction of the thickness of the layer to form a minority carrier mirror within the layer. The p-type layer in the thin film heterojunction solar cell is formed by independently controlling the vaporization rate of the elements constituting the p-type layer. A composition gradient of Ga in the direction of the thickness across the mixed ternary thin film is used to form a minority carrier mirror within the p-type semiconductor.

U.S. Pat. No. 4,818,357 relates to a method and apparatus for sputter deposition of a semiconductor homojunction and the resulting semiconductor homojunction product. The inert gas pressure used in the method may be varied to create semiconductor layers of higher or lower resistivity. Thus, by sequentially varying the partial pressure of the inert gas, this method allows deposition of a semiconductor homojunction with a plurality of layers of varying conductivity type and resistivity. The method of sputter deposition of a semiconductor homo junction may include deposition of semiconductor compounds which are binary, ternary, quaternary, or pentenary. The method disclosed in this patent is particularly suited for sputter deposition of direct bandgap semiconductor compounds, especially copper indium selenide.

U.S. Pat. No. 4,465,575 relates to a method and apparatus for forming thin film photovoltaic cells employing multinary materials, such as I-III-VI₂ Cu-ternary chalcopyrite compounds. A semiconductor layer is initially provided with a composition gradient, either by varying the relative sputtering rates of the different constituent elements over time or passing the substrate over a number of magnetron sputtering arrangements which are adapted to sputter the constituent elements in different preselected proportions. It is therefore possible to deposit a single phase chalcopyrite layer in which the resistivity varies uniformly as a function of film depth.

Taiwanese Patent Publication No. 200832727 discloses a target for making a film layer of a thin film solar cell. The target includes a composition having a formula of IBₓ-IIIA_{y}-VIA_{z}, wherein IB is Cu, Ag, or a combination thereof, IIIA is In, Ga, or a combination thereof, VIA is S, Se, Te, or combinations thereof, x is equal to or greater than 0 and smaller than 1, y is greater than 0 and smaller than 1, z is greater than 0 and smaller than 1, and the sum of x, y, and z is equal to 1.

None of the afore said prior art discloses a compound film formed with substantially columnar grains so as to provide a thin film solar cell made thereby with improved electric property. Furthermore, none of the aforesaid prior art discloses that energy gap of a compound film layer of a thin film solar cell may be varied using different work pressures during a sputtering process, and that an interlayer may be included in a compound film layer of a thin film solar cell to control the size of columnar grains in the compound film layer.

### SUMMARY OF THE INVENTION

Therefore, an object of the present invention is to provide a target adapted for a sputtering process for making a compound film layer of a thin film solar cell having improved electric property.

Another object of the present invention is to provide a method of making the thin film solar cell.

Yet another object of the present invention is to provide the thin film solar cell made by the method.

In one aspect of this invention, a target adapted for a sputtering process for making a compound film layer of a thin film solar cell includes a composition having a formula of CuB₁₋ₓCₓSe_{y}S_{2-y}, wherein B and C are independently selected from Group IIIA elements; x ranges from 0 to 1; and y ranges from 0 to 2.

In another aspect of this invention, a method of making a thin film solar cell includes the steps of: a) cleaning a substrate; b) depositing a back electrode on the substrate using a first conductive material; c) depositing a compound film layer on the back electrode by sputtering using a target at a work temperature ranging from 150 to 600° C.; and d) depositing a top electrode on the compound film layer using a second conductive material.

In yet another aspect of this invention, a thin film solar cell includes a substrate, a back electrode deposited on the substrate, a compound film deposited on the back electrode and formed with substantially columnar grains, and a top electrode deposited on the compound film.

### BRIEF DESCRIPTION OF THE DRAWINGS

Other features and advantages of the present invention will become apparent in the following detailed description of the preferred embodiments with reference to the accompanying drawings, of which:

FIG. 1 is a fragmentary perspective view of a conventional thin film solar cell;

FIG. 2 is an electronic microscopic photo showing a grain structure of a compound film layer of copper indium gallium diselenide formed by thermal evaporation in the conventional thin film solar cell;

FIG. 3 is a flow chart illustrating a first preferred embodiment of a method of making a thin film solar cell according to this invention;

FIG. 4 is a fragmentary perspective view of a thin film solar cell made by the first preferred embodiment;

FIG. 5 is an electronic microscopic photo showing a grain structure of a compound film layer in the thin film solar cell made by the first preferred embodiment at a work temperature of 500° C.;

FIG. 6 is an electronic microscopic photo showing a grain structure of a compound film layer in the thin film solar cell made at a work temperature of 700° C.;

FIG. 7 is a plot illustrating a relationship between a size of columnar grains in the compound film layer and a thickness of an interlayer;

FIG. 8 is a flow chart illustrating a second preferred embodiment of a method of making a thin film solar cell according to this invention;

FIG. 9 is a fragmentary perspective view of a thin film solar cell made by the second preferred embodiment; and

FIG. 10 is a plot showing the energy gap of the compound film layer formed in the preferred embodiments versus the work pressure for sputtering.

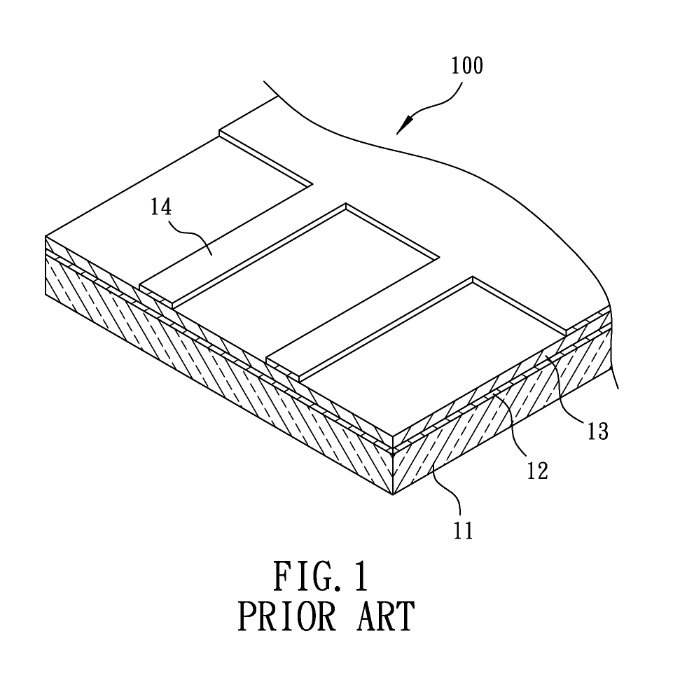

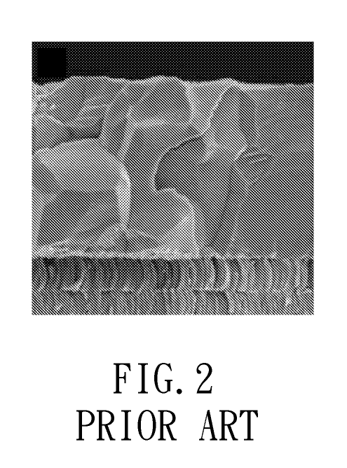

### DETAILED DESCRIPTION OF THE PREFERRED EMBODIMENTS

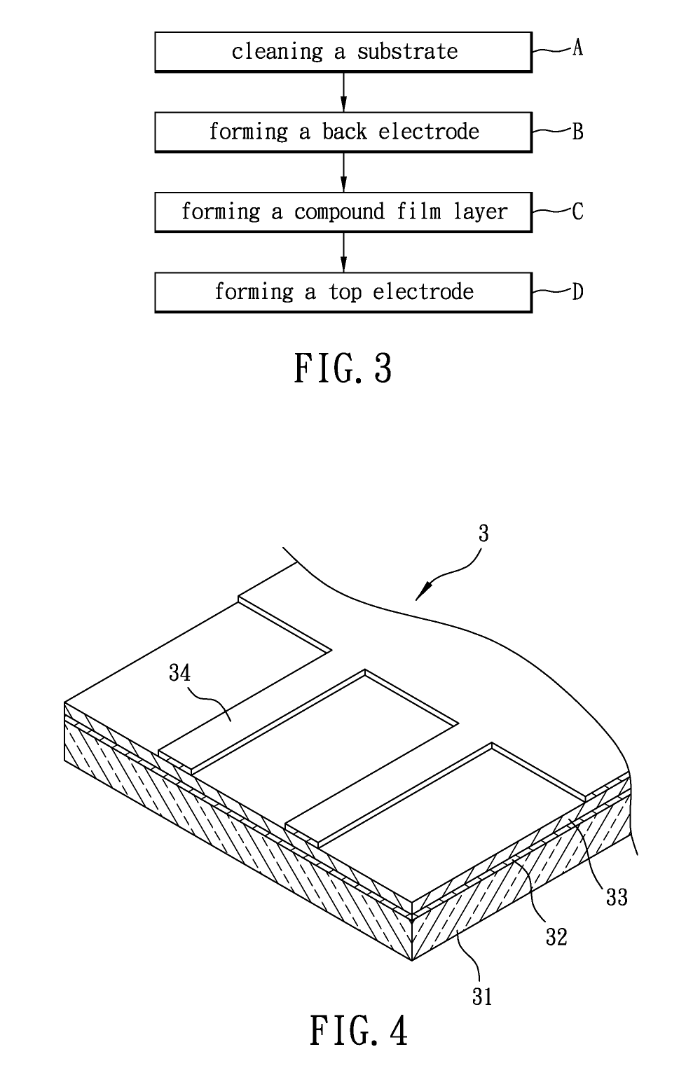

Referring to FIGS. 3 and 4, the first preferred embodiment of a method of making a thin film solar cell according to this invention is shown to include the steps of:

A) cleaning a substrate:
A substrate 31 is provided and is washed and dried according to a process commonly used in the art. The substrate 31 suitable for the present invention may be glass, a flexible foil of metal or alloy, or a polymer. In this preferred embodiment, soda glass is used for the substrate 31.

B) depositing a back electrode:
A back electrode 32 is deposited on the substrate 31 by a sputtering system using a first conductive material as a target. In this preferred embodiment, the first conductive material used as the target is molybdenum.

C) depositing a compound film layer:
A compound film layer 33 is deposited on the back electrode 32 by a sputtering system using a target at a work temperature ranging from 150 to 600° C. The target used in this step includes a composition having a formula of CuB₁₋ₓCₓSe_{y}S_{2-y}, wherein B and C are independently selected from Group IIIA elements; x ranges from 0 to 1; and y ranges from 0 to 2. Preferably, the Group IIIA elements include Al, Ga, and In. More preferably, one of B and C is In, and the other of B and C is Al or Ga. The compound film layer 33 formed in this step includes a composition having a formula of CuB₁₋ₓCₓSe_{y}S_{2-y}, wherein B and C are independently selected from Group IIIA elements; x ranges from 0 to 1; and y ranges from 0 to 2. Preferably, the Group IIIA elements include Al, Ga, and In. More preferably, one of B and C is In, and the other of B and C is Al or Ga.

D) forming a top electrode:
A top electrode 34 is deposited on the compound film layer 33 by a sputtering system using a second conductive material as a target. In this preferred embodiment, the second conductive material used as the target is aluminum.

Referring to FIG. 4, a thin film solar cell 3 made by the aforesaid method includes the substrate 31, the back electrode 32 deposited on the substrate 31, the compound film layer 33 deposited on the back electrode 32, and the top electrode 34 deposited on the compound film layer 33.

When the compound film layer 33 is irritated by light, it absorbs photons and produces photocurrent via a photovoltaic effect. The back electrode 32 forms an ohmic contact with the compound film layer 33 so as to favor the carrier transportation of the photocurrent.

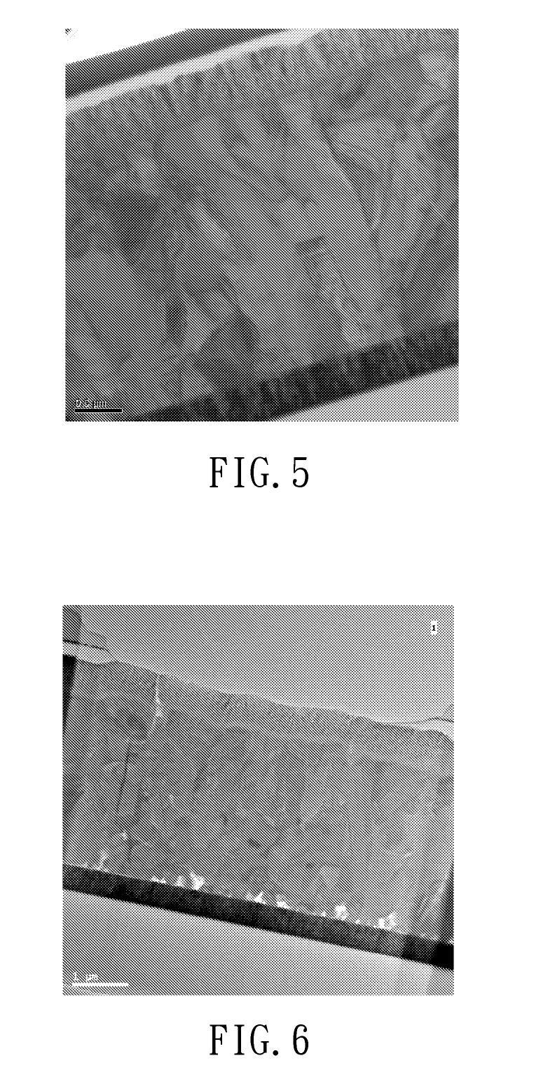

Referring to FIG. 5, the compound film layer 33 in the thin film solar cell 3 is formed at a work temperature of 500° C., and includes substantially columnar grains having a relatively uniform size distribution. The columnar grains tilt vertically relative to the substrate 31. This means that there is substantially no grain boundary extending in a direction substantially parallel to the surface of the compound film layer 33. Therefore, there is almost no grain boundary to block the carrier when transporting along a direction normal to the surface of the compound film layer 33. The electricity loss problem due to the grain boundary encountered in the prior art may be alleviated accordingly. Each of the columnar grains has an oblong section having a length equal to or smaller than a thickness of the compound film layer, and is in a form of a p-type semiconductor.

FIG. 6 illustrates an electronic microscopic photo of a grain structure of the compound film layer in the thin film solar cell made at a work temperatures of 700° C. As shown in the microscopic photo, the grain structure of the compound film layer is coaxial, rather than columnar. This means that there is a lot of grain boundary extending in a direction substantially parallel to the surface of the compound film layer 33. Therefore, the carriers are liable to be scattered and trapped due to the existence of the grain boundary, which results in electricity loss and reduces the efficiency of the solar cell.

Since the compound film layer 33 is formed by sputtering at an elevated temperature ranging from 150 to 600° C., the growth of the grains in the compound film layer 33 may be controlled so as to form the compound film layer 33 having the substantially columnar grains.

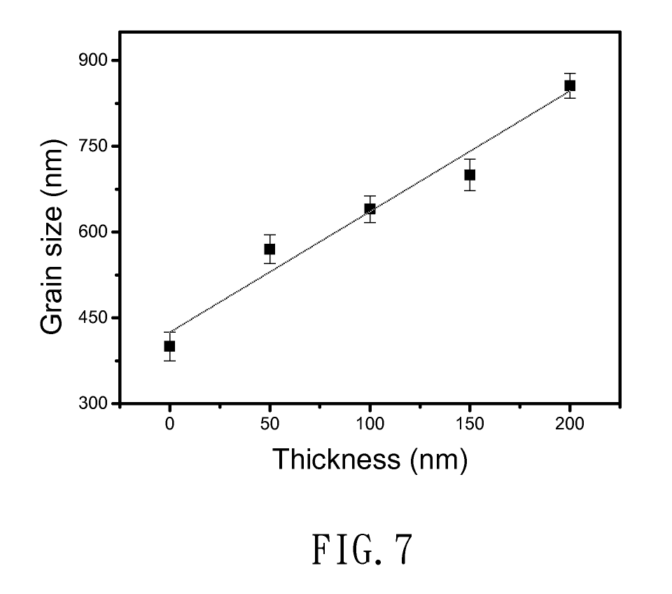

Preferably, the thin film solar cell 3 may further include at least one interlayer between the back electrode 32 and the compound film layer 33 to control the size of the columnar grains in the compound film layer 33. The interlayer is deposited on the back electrode 32 by a sputtering system using a material as a target such that the compound film layer 33 is deposited on the at least one interlayer. The material usable as the target may be represented by a formula of AₓSe₁₋ₓ, wherein x ranges from 0 to 0.7, and A is Cu, In, Ga, CuIn, GaIn, CuGa, or the like. A relationship between a size of columnar grains in the compound film layer 33 and a thickness of an interlayer of In₂Se₃ is illustrated in FIG. 7, in which the interlayer of In₂Se₃ is deposited on the back electrode 32 by sputtering at 500° C.

The thin film solar cell 3 may further include, between the top electrode 34 and the compound film layer 33, a cadmium sulfide buffering layer for enhancing the effective conduction of electrons, a zinc oxide film layer for preventing the compound film layer 33 from shunting when producing the photocurrent, and a transparent window layer of aluminum zinc oxide. Since these layers are well known structures in the art, they are not described in detail herein.

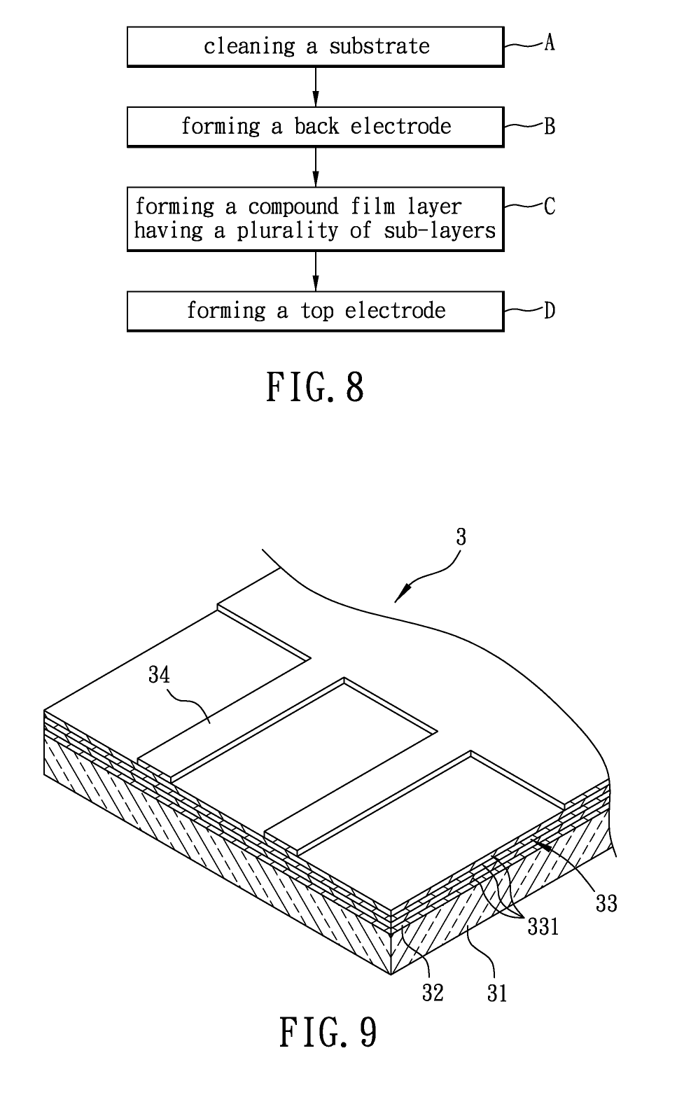

Referring to FIGS. 8 and 9, the second preferred embodiment of a method of making a thin film solar cell according to this invention is shown to be similar to the first preferred embodiment except that, in step C), the sputtering is performed repeatedly by varying a work pressure thereof ranging from 3 mTorr to 60 mTorr of argon to form a plurality of sub-layers 331 that constitute the compound film layer 33 and that have different compositions and different energy gaps. Specifically, two adjacent sub-layers 331 formed by two successive steps of sputtering have different energy gaps ranging from 1.02 eV to 1.68 eV.

In this preferred embodiment, the first sub-layer 331 is deposited on the back electrode 32 by sputtering at a work temperature of 500° C. and a work pressure of 10 mTorr of argon, and has an energy gap of 1.05 eV. The second sub-layer 331 is deposited on the first sub-layer 331 by sputtering at a work temperature of 500° C. and a work pressure of 20 mTorr of argon, and has an energy gap of 1.18 eV. The third sub-layer 331 is deposited on the second sub-layer 331 by sputtering at a work temperature of 500° C. and a work pressure of 30 mTorr of argon, and has an energy gap of 1.30 eV.

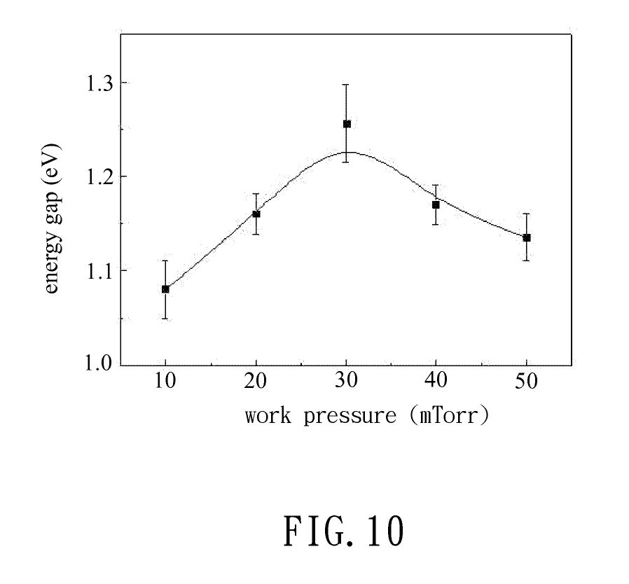

Referring to FIG. 10, a correlation of the energy gap of the compound film layer 33 with the work pressure of sputtering at a work temperature of 500° C. is shown. Therefore, in the present invention, the gradient of the energy gaps of the sub-layers 331 of the compound film layer 33 may be varied to suit the specific requirement.

Since the sub-layers 331 have different energy gaps, the range of the photons capable of being absorbed by the compound film layer 33 may be broadened, and the photoelectric conversion efficiency is further improved.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

We claim:

1. A target adapted for a sputtering process for making a compound film layer of a thin film solar cell, said target comprising:
a composition having a formula of CuB₁₋ₓCₓSe_{y}S_{2-y}, wherein
B and C are independently selected from Group IIIA elements;
x ranges from 0 to 1; and
y ranges from 0 to 2.

2. The target as claimed in claim 1, wherein said Group IIIA elements include Al, Ga, and In.

3. The target as claimed in claim 2, wherein one of B and C is In, and the other of B and C is Al or Ga.

4. A method of making a thin film solar cell, comprising the steps of:
a) cleaning a substrate;
b) depositing a back electrode on the substrate using a first conductive material;
c) depositing a compound film layer on the back electrode by sputtering using a target at a work temperature ranging from 150 to 600° C.; and
d) depositing a top electrode on the compound film layer using a second conductive material.

5. The method as claimed in claim 4, wherein, in step c), sputtering is performed repeatedly by varying a work pressure thereof to form a plurality of sub-layers that constitute the compound film layer and that have different compositions and different energy gaps.

6. The method as claimed in claim 5, wherein the step c) is conducted at a work pressure ranging from 3 mTorr to 60 mTorr of argon.

7. The method as claimed in claim 4, wherein the target includes a composition having a formula of CuB₁₋ₓCₓSe_{y}S_{2-y},
wherein
B and C are independently selected from Group IIIA elements;
x ranges from 0 to 1; and
y ranges from 0 to 2.

8. The method as claimed in claim 7, wherein the Group IIIA elements include Al, Ga, and In.

9. The method as claimed in claim 8, wherein one of B and C is In, and the other of B and C is Al or Ga.

10. The method as claimed in claim 4, further comprising a step of depositing at least one interlayer on the back electrode such that the compound film layer is deposited on said at least one interlayer in the step c).

11. The method as claimed in claim 10, wherein the interlayer is made using a material represented by a formula of AₓSe₁₋ₓ, wherein x ranges from 0 to 0.7, and A is selected from the group consisting of Cu, In, Ga, CuIn, GaIn, and CuGa.

12. A thin film solar cell, comprising:
a substrate;
a back electrode deposited on said substrate;
a compound film layer deposited on said back electrode and formed with substantially columnar grains; and
a top electrode deposited on said compound film layer.

13. The thin film solar cell as claimed in claim 12, wherein said columnar grains tilt vertically relative to said substrate.

14. The thin film solar cell as claimed in claim 12, wherein each of said columnar grains has an oblong section having a length equal to or smaller than a thickness of said compound film layer.

15. The thin film solar cell as claimed in claim 12, wherein said columnar grains are in a form of a p-type semiconductor.

16. The thin film solar cell as claimed in claim 12, wherein said compound film layer includes a plurality of sub-layers that have different compositions and different energy gaps.

17. The thin film solar cell as claimed in claim 16, wherein said energy gaps range from 1.02 to 1.68 eV.

18. The thin film solar cell as claimed in claim 12, further comprising at least one interlayer disposed between said back electrode and said compound film layer.

19. The thin film solar cell as claimed in claim 18, wherein said interlayer is made of a material represented by a formula of AₓSe₁₋ₓ, wherein x ranges from 0 to 0.7, and A is selected from the group consisting of Cu, In, Ga, CuIn, GaIn, and CuGa.
